(19) United States
(12) Patent Application Publication
(10) Pub. No.: US 2026/0334005 A1
(43) Pub. Date: Oct. 22, 2026

(54) DISPLAY DEVICE HAVING STACKED CIRCUIT ELEMENTS, METHOD OF PROVIDING THE SAME, AND ELECTRONIC DEVICE INCLUDING THE DISPLAY DEVICE

(71) Applicant: Samsung Display Co., LTD., Yongin-si (KR)

(72) Inventors: JOON SEOK PARK, Yongin-si (KR); SOYOUNG KOO, Yongin-si (KR); Minjae KIM, Yongin-si (KR); HYUNGJUN KIM, Yongin-si (KR); Aeran Song, Yongin-si (KR)

(21) Appl. No.: 19/444,454

(22) Filed: Jan. 9, 2026

(30) Foreign Application Priority Data
Apr. 18, 2025 (KR) 10-2025-0051052

(51) Int. Cl. H10K 59/121; H10K 59/12; H10K 59/131

(52) U.S. Cl. CPC H10K 59/1213; H10K 59/1201; H10K 59/131

(57) ABSTRACT

A display device includes a base substrate, a barrier layer on the base substrate, a lower back metal pattern penetrating the barrier layer at a trench of the barrier layer and including a protrusion or a recess which overlaps the trench, a lower transistor overlapping the lower back metal pattern and including a lower active layer and a lower gate electrode which is on the lower active layer, and a light-emitting element electrically connected to the lower transistor.

This application claims priority to Korean Patent Application No. 10-2025-0051052 filed on Apr. 18, 2025, and all the benefits accruing therefrom under 35 U.S.C. §119, the entire disclosure of which is incorporated herein by reference.

### BACKGROUND

### 1. Field

Embodiments of the present disclosure relate to a display device, a method of manufacturing (or providing) the display device, and an electronic device including the display device. More specifically, embodiments of the present disclosure relate to a display device including electrodes and transistors, a method of manufacturing (or providing) the display device, and an electronic device including the display device.

### 2. Description of the Related Art

In a display device such as organic light-emitting diode (OLED) display devices and liquid crystal display (LCD) devices, a display substrate including thin film transistors and various wirings may be provided, and a display structure including electrodes and light-emitting layers may be formed on the display substrate.

### SUMMARY

The electrodes of a display structure on a display substrate may include wirings and contact electrodes which electrically connect the transistor structure and the display structure to each other. As the number of stacked layers of the electrodes increases, a step difference may occur within the display structure, and defects due to the step difference may arise.

An object of the present disclosure is to provide a display device with improved structural reliability and electrical stability.

Another object of the present disclosure is to provide a method of manufacturing the display device.

Still another object of the present disclosure is to provide an electronic device including the display device.

According to embodiments of the present disclosure, a display device may include a base substrate, a barrier layer on the base substrate, a lower back metal pattern penetrating the barrier layer and including a protrusion or a recess, a lower transistor on the lower back metal pattern and including a lower active layer and a lower gate electrode on the lower active layer, and a light-emitting element electrically connected to the lower transistor.

In some embodiments, the display device may further include a lower contact electrode electrically connected to the lower active layer and a lower back contact electrically connected to the lower back metal pattern. In addition, the lower back contact and the lower contact electrode may be connected to each other.

In some embodiments, the display device may further include a lower gate contact electrically connected to the lower gate electrode and a lower back contact electrically connected to the lower back metal pattern. In addition, the lower back contact and the gate contact may be connected to each other.

In some embodiments, the base substrate may include a display area and a peripheral circuit area. In addition, the lower back metal pattern may include a first lower back metal pattern disposed on the display area of the base substrate and a second lower back metal pattern disposed on the peripheral circuit area of the base substrate. Furthermore, each of the first lower back metal pattern and the second lower back metal pattern may include the protrusion or the recess.

In some embodiments, the lower transistor may include a first lower transistor disposed on the display area of the base substrate and a second lower transistor disposed on the peripheral circuit area of the base substrate.

In some embodiments, the display device may further include a first lower back contact electrically connecting the first lower transistor to the first lower back metal pattern and a second lower back contact electrically connecting the second lower transistor to the second lower back metal pattern.

In some embodiments, the display device may further include a storage capacitor on the first lower transistor in the display area of the base substrate.

In some embodiments, the display device may further include a first upper back metal pattern disposed between the first lower transistor and the storage capacitor.

In some embodiments, the display device may further include a second upper transistor on the second lower transistor in the peripheral circuit area of the base substrate.

In some embodiments, the display device may further include contact electrodes electrically connecting the second upper transistor and the second lower transistor to each other.

In some embodiments, the display device may further include a second upper back metal pattern disposed between the second lower transistor and the second upper transistor.

In some embodiments, a lower surface of the lower back metal pattern may be in contact with the base substrate.

In some embodiments, the lower back metal pattern may include the protrusion, and a thickness of the protrusion may be smaller than a thickness of a peripheral region of the lower back metal pattern excluding the protrusion.

In some embodiments, the lower back metal pattern may include the recess, and a depth of the recess may be less than or equal to 1/2 of a total thickness of the lower back metal pattern.

In some embodiments, an upper surface of a peripheral region of the recess or the protrusion of the lower back metal pattern may be coplanar with an upper surface of the barrier layer.

According to embodiments of the present disclosure, a method of manufacturing a display device may include forming a barrier layer on a base substrate, forming a trench which penetrates the barrier layer by partially etching the barrier layer, sequentially forming a lower back metal layer which fills the trench and a sacrificial layer on the base substrate, forming a lower back metal pattern within the trench by planarizing the sacrificial layer and the lower back metal layer through an etch-back process, forming a lower transistor on the lower back metal pattern, and forming a light-emitting element electrically connected to the lower transistor.

In some embodiments, the etch-back process may be performed under a condition that an etching rate for the lower back metal layer is greater than an etching rate for the sacrificial layer. In addition, a protrusion may be provided at an upper surface of the lower back metal pattern.

In some embodiments, the etch-back process may be performed under a condition that an etching rate for the lower back metal layer is lower than an etching rate for the sacrificial layer. In addition, a recess may be provided at an upper surface of the lower back metal pattern.

According to embodiments of the present disclosure, an electronic device may include a display device, a memory device, and a processor configured to execute data included in the memory device to control an operation of the display device. In addition, the display device may include a base substrate, a barrier layer on the base substrate, a lower back metal pattern penetrating the barrier layer and including a protrusion or a recess, a lower transistor on the lower back metal pattern and including a lower active layer and a lower gate electrode on the lower active layer, and a light-emitting element electrically connected to the lower transistor.

In some embodiments, the electronic device may be implemented as virtual reality glasses, augmented reality glasses, a smartphone, a tablet computer, a laptop, a television, a desk monitor, smart glasses, a head-mounted display, a smart watch, or a vehicle display.

Therefore, according to embodiments of the present disclosure, a lower back metal pattern may be embedded in a barrier layer, thereby suppressing a step difference of a thin film transistor array substrate from below. Accordingly, disconnection or short-circuits of an active layer or electrodes due to the step difference may be prevented, and thus structural stability of the display device may be enhanced.

According to embodiments, the lower back metal pattern may include protrusions or recesses, which can more effectively implement source-sink characteristics enhancement or step difference prevention.

### BRIEF DESCRIPTION OF THE DRAWINGS

The above and other advantages and features of this disclosure will become more apparent by describing in further detail embodiments thereof with reference to the accompanying drawings, in which:

FIG. 1 is a schematic plan view illustrating a display device according to embodiments.

FIG. 2 is a schematic cross-sectional view illustrating a display device according to embodiments.

FIG. 3 is a partially enlarged cross-sectional view illustrating a shape of a lower back metal pattern of a display device according to embodiments.

FIGS. 4 to 9 are schematic cross-sectional views illustrating a method of manufacturing (or providing) a display device according to embodiments.

FIG. 10 is a schematic cross-sectional view illustrating a display device according to embodiments.

FIG. 11 is a partially enlarged cross-sectional view illustrating a shape of a lower back metal pattern of a display device according to embodiments.

FIGS. 12 to 15 are schematic cross-sectional views illustrating a method of manufacturing (or providing) a display device according to embodiments.

FIG. 16 is an exploded perspective view illustrating an electronic device according to embodiments.

FIG. 17 is a block diagram illustrating an electronic device according to embodiments.

FIG. 18 is schematic diagrams of embodiments of the electronic device of FIG. 17.

### DETAILED DESCRIPTION

Hereinafter, embodiments of the present disclosure will be described in more detail with reference to the accompanying drawings. The same reference numerals are used for the same constituent elements in the drawings, and redundant descriptions for the same constituent elements will be omitted. The embodiments disclosed in the accompanying drawings are exemplary, and it should be understood that those include all modifications, equivalents, and substitutes included within the spirit and technical scope of the present disclosure. Within the Figures and the text of the disclosure, a reference number indicating a singular form of an element may also be used to reference a plurality of the element.

Terms used in this specification such as "on," "connected", "coupled", and/or the like include not only direct placement/connection/coupling but also cases where another component is interposed. As used herein, when an element is referred to as being related to another element such as being “directly on,” “directly connected” to, “directly coupled” to, etc. another element, there are no intervening elements present.

Terms such as "first", "second", "below", "lower side", "above", "upper side", and/or the like are used as relative concepts to distinguish different components or positions and do not specify an absolute position or order. For example, “a first element,” “component,” “region,” “layer” or “section” discussed below could be termed a second element, component, region, layer or section without departing from the teachings herein. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

The terminology used herein is for the purpose of describing particular embodiments only and is not intended to be limiting. As used herein, "a", "an," "the," and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, "an element" has the same meaning as “at least one element," unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

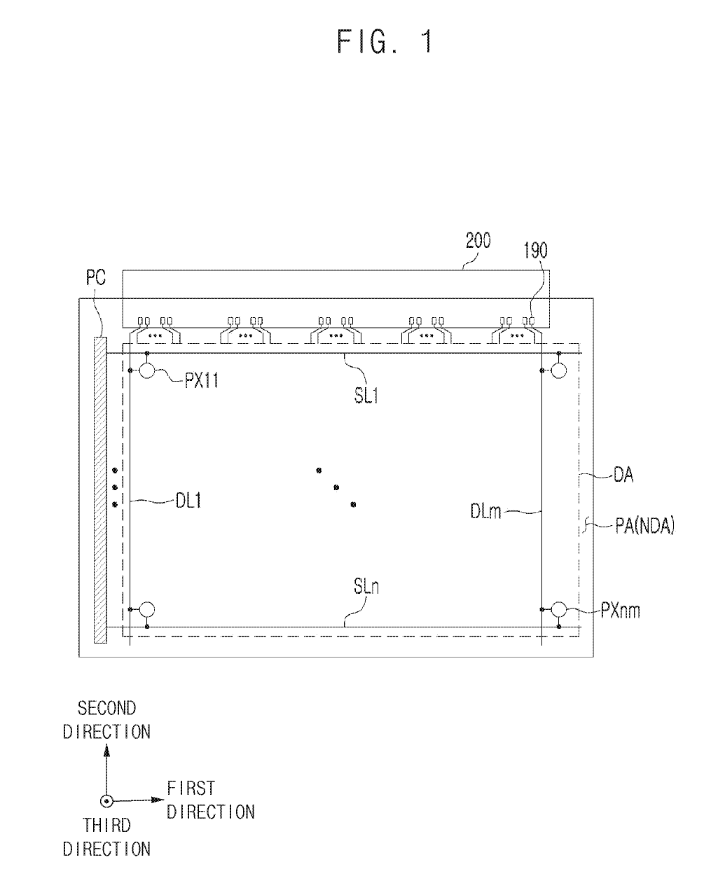

FIG. 1 is a schematic plan view illustrating a pixel array of a display device according to embodiments.

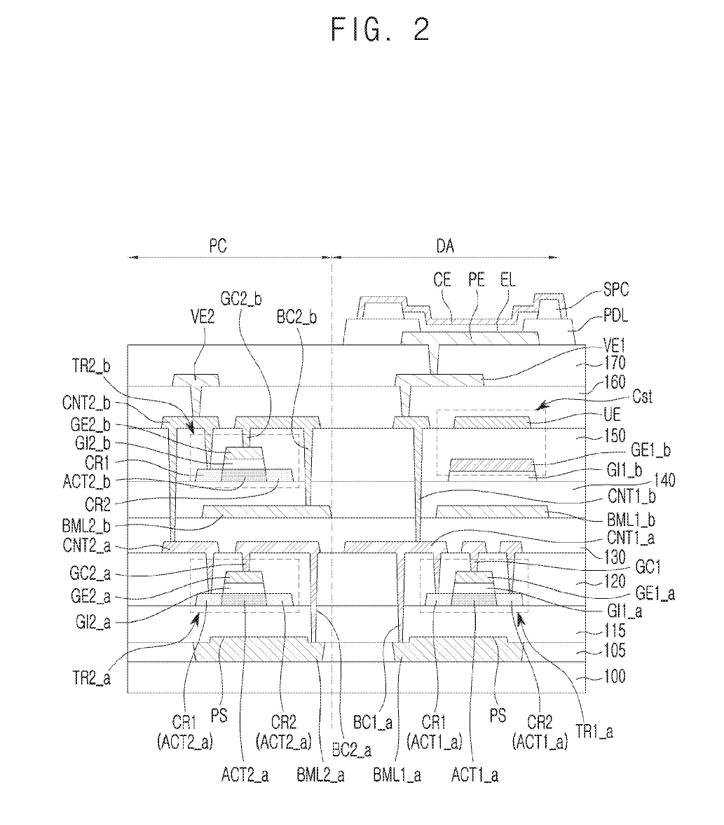

In FIG. 1, a first direction and a second direction may refer to two directions which are parallel to an upper surface of a base substrate 100 (see FIG. 2) or a display surface of the display device. The first direction and the second direction cross each other, such as to be perpendicular to each other. The first direction and the second direction crossing each other may define a plane. For example, the first direction may correspond to the X direction (e.g., a row direction) of the display device, and the second direction may correspond to the Y direction (e.g., a column direction) of the display device.

A third direction may cross both the first direction and the second direction, such as to be perpendicular to the first direction and the second direction. The third direction may correspond to the Z direction (e.g., a thickness direction) of the display device. That is, a thickness of the display device and various components or layers thereof may be extended in the third direction.

Referring to FIG. 1, a plurality of pixels PX11 to PXnm may be arranged in a display area DA of the display device or the base substrate 100.

According to embodiments, a pixel circuit including scan lines SL1 to SLn (or also referred to as gate lines) forming first to n-th rows, and data lines DL1 to DLm forming first to m-th columns, may be arranged on the base substrate 100. Each of the pixels PX11 to PXnm may be connected to a corresponding n-th row scan line among the scan lines SL1 to SLn and a corresponding m-th column data line among the data lines DL1 to DLm.

For example, the scan lines SL1 to SLn may be connected to a gate electrode included in a thin-film transistor. The data lines DL1 to DLm may be connected to, for example, a contact electrode (e.g., a first contact electrode CNT1 or a third contact electrode CNT3) provided as a source electrode.

Each of the pixels PX11 to PXnm may include a pixel circuit including a transistor and a light-emitting element, as will be described later. Although not shown in detail in FIG. 1, the pixel circuit may further include wirings such as a power line, a ground line, and/or the like.

In FIG. 1, the data lines DL1 to DLm are shown extending in the second direction, and the scan lines SL1 to SLn are shown extending in the first direction, but it is not necessarily limited thereto.

The non-display area NDA of the display device may include a peripheral circuit area PC. For example, the peripheral circuit area PC may include a gate driving circuit. The gate driving circuit may be integrated into the display device through an oxide semiconductor gate (OSG) driving circuit process, an amorphous silicon gate (ASG) driving circuit process, or a polysilicon gate (PSG) driving circuit process.

The peripheral circuit area PC may further include a data driver, a gate driver, a light-emitting driver, a power voltage generator, a timing controller, and/or the like.

The display device may further include a printed circuit board 200. A pad 190 provided in plural includes pads 190 of the pixel circuit (e.g., the data lines) which may be gathered on one side of the non-display area NDA.

The printed circuit board 200 may be electrically connected to the pixel circuit through the pads 190. For example, the printed circuit board 200 as a circuit board may be electrically connected to the pads 190 through a heating-compression process using a conductive intermediate structure such as an anisotropic conductive film ACF.

The pads 190 and an integrated circuit (IC) such as a data driving circuit may be electrically connected to each other, through the printed circuit board 200. In some embodiments, an integrated circuit (IC) chip may be mounted on the printed circuit board 200 in a chip-on-film (COF) form.

FIG. 2 is a schematic cross-sectional view illustrating a display device according to embodiments. For convenience of illustration, in FIG. 2, insulating layers (e.g., a barrier layer, a buffer layer, an interlayer insulating layer, and/or the like) are shown as having a flat upper surface, but the insulating layers may have a step difference following a profile of the underlying structure they cover. According to embodiments, the step difference may be reduced by a structure/shape of the lower back contact.

Referring to FIG. 2, as described above, the display device may include the display area DA and the peripheral circuit area PC which is adjacent to the display area DA. Accordingly, the base substrate 100 may also include the display area DA and the peripheral circuit area PC. For convenience of explanation, only transistors and a light-emitting element included in one pixel within the display area DA are shown in FIG. 2.

A first lower transistor TR1_a and a light-emitting element which is electrically connected to the first lower transistor TR1_a may be stacked in the display area DA of the base substrate 100. The light-emitting element may include a pixel electrode PE, a light-emitting part EL, and a counter electrode CE.

In some embodiments, a storage capacitor Cst may be stacked on the first lower transistor TR1_a.

Transistors may be formed in the peripheral circuit area PC of the base substrate 100 through a gate driver integration process as described above.

According to embodiments, a second lower transistor TR2_a and a second upper transistor TR2_b may be sequentially stacked in a vertical direction or a thickness direction (e.g., the third direction) from the upper surface of the base substrate 100 of the peripheral circuit area PC. The second lower transistor TR2_a and the second upper transistor TR2_b may overlap each other in the vertical direction. As being overlapping, elements may be disposed along a same line in a direction, such as along a thickness (vertical) direction, a lateral (horizontal or planar) direction, etc. For example, one element may be above or below another element along a thickness direction, so as to be be considered overlapping each other, without being limited thereto.

As described above, a size (e.g., a planar area, like along a plane defined by the first direction and the second direction) of the peripheral circuit area PC may be reduced by stacking a plurality of transistors in the vertical direction in the peripheral circuit area PC. Therefore, for example, a size of the display area DA may be relatively increased while reducing the size of a bezel area (e.g., corresponding to a non-display area NDA and/or a peripheral circuit area PC) of the display device.

The base substrate 100 may be provided as a support substrate or a back-plane substrate of a display panel and/or the display device. A glass substrate or a plastic substrate may be used as the base substrate 100.

In some embodiments, the base substrate 100 may include a polymer material having transparency and a certain degree of flexibility. For example, the base substrate 100 may include a polymer material such as polyimide, polysiloxane, epoxy-based resin, acrylic-based resin, or polyester. In an embodiment, the base substrate 100 may include polyimide.

In some embodiments, a glass substrate may be used as the base substrate 100.

The barrier layer 105 may be formed on the upper surface of the base substrate 100. The barrier layer 105 may block moisture penetrating through the base substrate 100 and may block the diffusion of impurities between the base substrate 100 and the structure formed on the base substrate 100. A solid (material) portion of the barrier layer 105 may cover the entire upper surface of the base substrate 100, except for trenches defined by the solid portion. The trenches may penetrate completely through a thickness of the barrier layer 105, such as to be open at both the upper surface 105a and the lower surface of the barrier layer 105. The base substrate 100 may be exposed to outside the barrier layer 105 at the trenches.

The barrier layer 105 may include an inorganic insulating material such as, for example, silicon oxide, silicon nitride, or silicon oxynitride. These may be used alone or in a combination of two or more. In some embodiments, the barrier layer 105 may have a stacked structure including a silicon oxide film and a silicon nitride film. In some embodiments, the barrier layer 105 may also include an organic layer and may have a multi-layer structure of an organic layer and an inorganic layer.

According to embodiments, a lower back metal pattern which penetrates the barrier layer 105 at a trench, may be formed on the base substrate 100. The lower back metal pattern as a lower back metal layer may be provided in plural including a first lower back metal pattern BML1_a formed (or provided) on the base substrate 100 of the display area DA and a second lower back metal pattern BML2_a formed on the base substrate 100 of the peripheral circuit area PC.

The lower back metal patterns BML1_a and BML2_a may be in a same layer as each other. As being in a same layer, elements may be formed in a same process and/or include a same material as each other, elements may be respective portions of a same material layer, elements may be on a same layer by forming an interface with a same underlying or overlying layer, elements may be coplanar with each other or be disposed in a same thickness, etc., without being limited thereto.

The lower back metal patterns BML1_a and BML2_a may include a metal such as silver (Ag), tungsten (W), molybdenum (Mo), aluminum (Al), copper (Cu), titanium (Ti), chromium (Cr), nickel (Ni), tantalum (Ta), platinum (Pt), palladium (Pd), and/or the like or an alloy containing at least one of these.

The lower back metal patterns BML1_a and BML2_a may be provided as a light-blocking layer of external light for the first lower transistor TR1_a and the second lower transistor TR2_a. The lower back metal patterns BML1_a and BML2_a may also be provided as bias electrodes.

In an embodiment, the lower back metal patterns BML1_a and BML2_a may be provided as a back gate or a source-sink electrode connected (e.g., electrically connected) to the first lower transistor TR1_a or the second lower transistor TR2_a. In an embodiment, the lower back metal patterns BML1_a and BML2_a may also be provided as a floating electrode or an island electrode separated (e.g., electrically isolated) from the first lower transistor TR1_a or the second lower transistor TR2_a.

The lower back metal patterns BML1_a and BML2_a may be an electrode pattern which penetrates the barrier layer 105. According to embodiments, the lower back metal patterns BML1_a and BML2_a may completely penetrate a thickness of the barrier layer 105. In some embodiments, the lower back metal patterns BML1_a and BML2_a may penetrate the barrier layer 105 and be in contact with the upper surface of the base substrate 100. As being in contact, elements may form an interface therebetween.

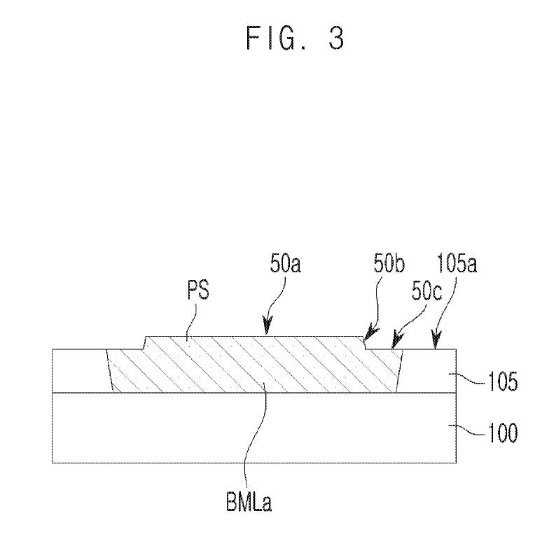

According to the embodiment shown in FIG. 2, the lower back metal patterns BML1_a and BML2_a may include a protrusion PS which overlaps the trench. A shape of the lower back metal patterns BML1_a and BML2_a including the protrusion PS will be described in more detail with reference to FIG. 3.

A first buffer layer 115 may be formed on the barrier layer 105 to cover the lower back metal patterns BML1_a and BML2_a. The first buffer layer 115 may further prevent the penetration of impurities into lower active layers ACT1_a and ACT2_a of the lower transistors TR1_a and TR2_b. The first buffer layer 115 may include an inorganic insulating material such as silicon nitride, silicon oxide, and/or silicon oxynitride. The first buffer layer 115 may have a single-layer structure or a multi-layer structure including the aforementioned inorganic insulating materials.

A lower transistor may be provided in plural including the first lower transistor TR1_a and the second lower transistor TR2_a may be disposed on the first buffer layer 115. The first lower transistor TR1_a may include the first lower active layer ACT1_a, a first lower gate insulating layer GI1_a, and a first lower gate electrode GE1_a. The second lower transistor TR2_a may include the second lower active layer ACT2_a, a second lower gate insulating layer GI2_a, and a second lower gate electrode GE2_a.

The first lower active layer ACT1_a and the second lower active layer ACT2_a of a lower active layer may be formed on the first buffer layer 115. The first lower active layer ACT1_a and the second lower active layer ACT2_a may include a silicon compound such as polysilicon or amorphous silicon, or an oxide semiconductor. According to embodiments, the first lower active layer ACT1_a and the second lower active layer ACT2_a may also include an oxide semiconductor such as Indium Gallium Zinc Oxide (IGZO), Zinc Tin Oxide (ZTO), or ITZO.

For example, an oxide semiconductor layer may be formed on the first buffer layer 115 through a deposition process such as a sputtering process. The oxide semiconductor layer of the lower active layer may be patterned through a photolithography process to form the first lower active layer ACT1_a and the second lower active layer ACT2_a in the display area DA and the peripheral circuit area PC, respectively.

A first contact region CR1 and a second contact region CR2 may be formed on one side and the other side of each of the first lower active layer ACT1_a and the second lower active layer ACT2_a, respectively. The first contact region CR1 and the second contact region CR2 may be provided as a source region and a drain region, respectively. A portion of the lower active layers ACT1_a and ACT2_a between the first contact region CR1 and the second contact region CR2 may be defined as a channel region.

The first lower gate insulating layer GI1_a and the second lower gate insulating layer GI2_a of a lower gate insulating layer may be disposed on the channel regions of the first lower active layer ACT1_a and the second lower active layer ACT2_a, respectively. The first lower gate electrode GE1_a and the second lower gate electrode GE2_a may be disposed on the first lower gate insulating layer GI1_a and the second lower gate insulating layer GI2_a, respectively.

In some embodiments, the first lower gate insulating layer GI1_a and the second lower gate insulating layer GI2_a may be formed in a pattern shape which selectively covers the channel regions. As being a pattern shape, an element may have a discrete shape in the plan view (e.g., a planar shape).

According to embodiments, a lower gate insulating layer may be formed on the first buffer layer 115 through a deposition process such as a chemical vapor deposition (CVD) process to include the aforementioned inorganic insulating material such as silicon oxide, silicon nitride, silicon oxynitride, and/or the like. The lower gate insulating layer may also be formed to include an inorganic insulating material such as aluminum oxide, titanium oxide, tantalum oxide, hafnium oxide, and/or the like.

A lower gate electrode layer may be formed on the lower gate insulating layer through a deposition process such as a sputtering process to include the aforementioned metal or alloy. The lower gate electrode layer may be patterned through a photolithography process to form the first lower gate electrode GE1_a and the second lower gate electrode GE2_a.

Subsequently, the lower gate insulating layer may be patterned through an etching process using the first lower gate electrode GE1_a and the second lower gate electrode GE2_a as an etching mask. Through this etching process, the first lower gate insulating layer GI1_a may be formed between the channel region of the first lower active layer ACT1_a and the first lower gate electrode GE1_a, and the second lower gate insulating layer GI2_a may be formed between the channel region of the second lower active layer ACT2_a and the second lower gate electrode GE2_a.

In some embodiments, the lower gate insulating layer may be included as a common gate insulating layer for a plurality of transistors included in the display area DA instead of having patterns of the first lower gate insulating layer GI1_a and the second lower gate insulating layer GI2. Here, the lower gate insulating layer may also be included as the gate insulating layer of the second lower transistor TR2_a. In this case, the aforementioned etching process for the lower gate insulating layer may be omitted.

A first interlayer insulating layer 120 may be formed on the first buffer layer 115 to cover the lower transistors TR1_a and TR2_a. The first interlayer insulating layer 120 may be formed through a deposition process such as a CVD process to include the aforementioned inorganic insulating material.

In some embodiments, vacancy sites due to etching damage may be induced on side surfaces of the lower active layers ACT1_a and ACT2_a by the etching process of the lower gate insulating layer. As the first interlayer insulating layer 120 is formed, hydrogen included in the first interlayer insulating layer 120 may move to the side surfaces of the lower active layers ACT1_a and ACT2_a, and thus the contact regions CR1 and CR2 with increased conductivity compared to the channel region may be formed.

Lower contact electrodes CNT1_a and CNT2_a may be formed on the first interlayer insulating layer 120. The lower contact electrodes CNT1_a and CNT2_a of a lower contact electrode layer may penetrate the first interlayer insulating layer 120 to be in contact with or electrically connected to the contact regions CR1 and CR2 of the lower active layers ACT1_a and ACT2_a.

A first lower contact electrode CNT1_a may be formed on the first interlayer insulating layer 120 in the display area DA and may be in contact with or electrically connected to each of the first contact region CR1 and/or the second contact region CR2 of the first lower active layer ACT1_a.

A second lower contact electrode CNT2_a may be formed on the first interlayer insulating layer 120 in the peripheral circuit area PC and may be in contact with or electrically connected to the first contact region CR1 and/or the second contact region CR2 of the second lower active layer ACT2_a.

In some embodiments, lower gate contacts GC1 and GC2_a may be formed on the first interlayer insulating layer 120 and may be in contact with or electrically connected to the lower gate electrodes GE1_a and GE2_a._

A first lower gate contact GC1 may penetrate the first interlayer insulating layer 120 to be in contact with or electrically connected to the upper surface of the first lower gate electrode GE1_a of the first lower transistor TR1_a.

A second lower gate contact GC2_a may penetrate the first interlayer insulating layer 120 to be in contact with or electrically connected to the upper surface of the second lower gate electrode GE2_a of the second lower transistor TR2_a.

In some embodiments, a lower back contact which is in contact with or electrically connected to the lower back metal patterns BML1_a and BML2_a may be further formed. The lower back contact may include a first lower back contact BC1_a and a second lower back contact BC2_a formed in the display area DA and the peripheral circuit area PC, respectively.

The first lower back contact BC1_a may penetrate the first interlayer insulating layer 120 and the first buffer layer 115 to be in contact with or electrically connected to the first lower back metal pattern BML1_a. The second lower back contact BC2_a may penetrate the first interlayer insulating layer 120 and the first buffer layer 115 to be in contact with or electrically connected to the second lower back metal pattern BML2_a.

According to embodiments, the first lower back contact BC1_a may be connected to the first lower contact electrode CNT1_a to provide a lower contact pattern. In an embodiment, the first lower back contact BC1_a may be integrally connected to the first lower contact electrode CNT1_a (e.g., unitary body) on the upper surface of the first interlayer insulating layer 120. Accordingly, the first lower back metal pattern BML1_a may be provided as, for example, a source-sink electrode. For example, a lower contact pattern which electrically connects the lower active layer to the lower back metal pattern may include a lower contact electrode (like CNT1-a) at which the lower contact pattern is electrically connected to the lower active layer (like ACT1_a), and a lower back contact (like BC1_a) at which the lower contact pattern is electrically connected to the lower back metal pattern (like BML1_a).

According to embodiments, the second lower back contact BC2_a may be connected to the second lower gate contact GC2_a. In an embodiment, the second lower back contact BC2_a may be integrally connected to the second lower gate contact GC2_a (e.g., unitary body) on the upper surface of the first interlayer insulating layer 120. Accordingly, the second lower back metal pattern BML2_a may be provided as, for example, a lower back gate electrode. For example, the second lower transistor TR2_a may have a double gate structure by the second lower back metal pattern BML2_a. In an embodiment, a lower contact pattern which electrically connects the lower gate electrode (like GC2_a) to the lower back metal pattern (like BML2_a) may include a lower gate contact (like GC2_a) at which the lower contact pattern is electrically connected to the lower gate electrode, and a lower back contact (like BC2_a) at which the lower contact pattern is electrically connected to the lower back metal pattern (like BML2_a).

For example, the first interlayer insulating layer 120 may be etched to form lower contact holes which expose the upper surfaces of the contact regions CR1 and CR2 and the lower gate electrodes GE1_a and GE2_a to outside the first interlayer insulating layer 120. The first buffer layer 115 may be additionally etched to form lower back contact holes which expose the upper surfaces of the lower back metal patterns BML1_a and BML2_a to outside the first buffer layer 115.

A lower contact electrode layer containing the aforementioned metal or alloy may be formed on the first interlayer insulating layer 120 through a deposition process such as a sputtering process to fill the lower contact holes and the lower back contact holes. The lower contact electrode layer may be etched to form the lower contact electrodes CNT1_a and CNT2_a, the lower gate contacts GC1 and GC2_a, and the lower back contacts BC1_a and BC2_a.

In some embodiments, the lower contact electrode layer may be formed to have a multi-layer structure including a plurality of metal layers (e.g., Ti layer/Al layer/Ti layer).

A second interlayer insulating layer 130 covering the lower contact electrodes CNT1_a and CNT2_a, the lower gate contacts GC1 and GC2_a, and the lower back contacts BC1_a and BC2_a may be formed on the first interlayer insulating layer 120. The second interlayer insulating layer 130 may be formed through a deposition process such as a CVD process to include the aforementioned inorganic insulating material.

An upper back metal pattern may be formed on the second interlayer insulating layer 130. For example, a first upper back metal pattern BML1_b may be formed on the second interlayer insulating layer 130 in the display area DA. A second upper back metal pattern BML2_b may be formed on the second interlayer insulating layer 130 in the peripheral circuit area PC.

For example, an upper back metal layer containing the aforementioned metal or alloy may be formed on the second interlayer insulating layer 130 through a deposition process such as a sputtering process. The upper back metal layer may be etched through a photolithography process to form the first upper back metal pattern BML1_b and the second upper back metal pattern BML2_b.

The first upper back metal pattern BML1_b and the second upper back metal pattern BML2_b may be provided as a light-blocking layer for an upper structure including the storage capacitor Cst and the second upper transistor TR2_b, a back gate electrode, a source-sink electrode, and/or the like.

A second buffer layer 140 covering the first upper back metal pattern BML1_b and the second upper back metal pattern BML2_b may be formed on the second interlayer insulating layer 130. The second buffer layer 140 may be formed through a deposition process such as a CVD process to include the aforementioned inorganic insulating material.

The second buffer layer 140 may block or reduce the penetration of impurities into, for example, the second upper active layer ACT2_b of the second upper transistor TR2_b.

According to embodiments, the storage capacitor Cst and the second upper transistor TR2_b may be disposed on the second buffer layer 140 in the display area DA and the peripheral circuit area PC, respectively.

The second upper transistor TR2_b may include a second upper active layer ACT2_b, a second upper gate insulating layer GI2_b, and a second upper gate electrode GE2_b.

The second upper active layer ACT2_b may be formed on the second buffer layer 140. The second upper active layer ACT2_b may include a silicon compound such as polysilicon or amorphous silicon, or an oxide semiconductor. According to embodiments, the second upper active layer ACT2_b may also include an oxide semiconductor such as Indium Gallium Zinc Oxide (IGZO), Zinc Tin Oxide (ZTO), or ITZO.

For example, an oxide semiconductor layer may be formed on the second buffer layer 140 through a deposition process such as a sputtering process. The oxide semiconductor layer may be patterned through a photolithography process to form the second upper active layer ACT2_b in the peripheral circuit area PC.

A first contact region CR1 and a second contact region CR2 may be formed on one side and the other side of the second upper active layer ACT2_b, respectively. The first contact region CR1 and the second contact region CR2 may be provided as a source region and a drain region, respectively. A portion of the second upper active layer ACT2_b between the first contact region CR1 and the second contact region CR2 may be defined as a channel region.

The second upper gate insulating layer GI2_b may be disposed on the channel region of the second upper active layer ACT2_b. A second upper gate electrode GE2_b may be disposed on the second upper gate insulating layer GI2_b.

As shown in FIG. 2, the second upper gate insulating layer GI2_b may be formed in a pattern shape which selectively covers the channel region.

According to embodiments, an upper gate insulating layer may be formed on the second buffer layer 140 through a deposition process such as a CVD process to include the aforementioned inorganic insulating material. The upper gate insulating layer may cover the second upper active layer ACT2_b.

An upper gate electrode layer may be formed on the upper gate insulating layer through a deposition process such as a sputtering process to include the aforementioned metal or alloy. The upper gate electrode layer may be patterned through a photolithography process to form the second upper gate electrode GE2_b.

According to embodiments, along with the second upper gate electrode GE2_b, a first upper gate electrode GE1_b may be formed from the upper gate electrode layer in the display area DA.

Subsequently, the upper gate insulating layer may be patterned through an etching process using the first upper gate electrode GE1_b and the second upper gate electrode GE2_b as an etching mask. Through this etching process, a first upper gate insulating layer GI1_b may be formed on the second buffer layer 140 in the display area DA. A second upper gate insulating layer GI2_b may be formed between the channel region of the second upper active layer ACT2_b formed in the peripheral circuit area PC and the second upper gate electrode GE2_b.

A third interlayer insulating layer 150 may be formed on the second buffer layer 140 to cover the first upper gate electrode GE1_b and the second upper transistor TR2_b. The third interlayer insulating layer 150 may be formed through a deposition process such as a CVD process to include the aforementioned inorganic insulating material.

In some embodiments, vacancy sites due to etching damage may be induced on the side surfaces of the second upper active layer ACT2_b by the etching process of the upper gate insulating layer. As the third interlayer insulating layer 150 is formed, hydrogen included in the third interlayer insulating layer 150 may move to the side surfaces of the second upper active layer ACT2b, and thus contact regions CR1 and CR2 with increased conductivity compared to the channel region may be formed.

Upper contact electrodes CNT1_b and CNT2_b may be formed on the third interlayer insulating layer 150. A first upper contact electrode CNT1_b may be in contact with or electrically connected to the first lower contact electrode CNT1_a. For example, the first upper contact electrode CNT1_b may penetrate the third interlayer insulating layer 150, the second buffer layer 140, and the second interlayer insulating layer 130 and may be in contact with or electrically connected to the upper surface of the first lower contact electrode CNT1_a.

The second upper contact electrode CNT2_b may include a portion which penetrates the third interlayer insulating layer 150 and is electrically connected to the contact regions CR1 and CR2 of the second upper active layer ACT2_b. The second upper contact electrode CNT2_b may further include a portion which penetrates the third interlayer insulating layer 150, the second buffer layer 140, and the second interlayer insulating layer 130 and is in contact with or electrically connected to the upper surface of the second lower contact electrode CNT2_a.

The second lower transistor TR2_a and the second upper transistor TR2_b may be electrically connected to each other and vertically stacked in the peripheral circuit area PC by the second upper contact electrode CNT2_b.

A second upper gate contact GC2_b and a second upper back contact BC2_b may be further formed on the third interlayer insulating layer 150.

The second upper gate contact GC2_b may penetrate the third interlayer insulating layer 150 to be in contact with or electrically connected to the upper surface of the second upper gate electrode GE2_b. The second upper back contact BC2_b may penetrate the third interlayer insulating layer 150 and the second buffer layer 140 to be in contact with or electrically connected to the upper surface of the second upper back metal pattern BML2_b.

The second upper gate contact GC2_b and the second upper back contact BC2_b may be formed as a single member integrally connected to each other (e.g., unitary body) on the upper surface of the third interlayer insulating layer 150. Accordingly, the second upper back metal pattern BML2_b may be provided as, for example, an upper back-gate electrode. For example, the second upper transistor TR2_b may have a double gate structure by the second upper back metal pattern BML2_b.

According to embodiments, an upper electrode UE which overlaps the first upper gate electrode GE1_b with the third interlayer insulating layer 150 interposed therebetween may be disposed on the upper surface of the third interlayer insulating layer 150. The storage capacitor Cst may be formed by the stacked structure of the first upper gate electrode GE1_b, the third interlayer insulating layer 150, and the upper electrode UE.

According to embodiments, the third interlayer insulating layer 150, the second buffer layer 140, and/or the second interlayer insulating layer 130 may be etched to form upper contact holes which expose the upper surfaces of the lower contact electrodes CNT1_a and CNT2_a and the second upper gate electrode GE2_b to outside of the insulating layer as the third interlayer insulating layer 150, the second buffer layer 140, and/or the second interlayer insulating layer 130. Along with the upper contact holes, an upper back contact hole exposing the upper surface of the second upper back metal pattern BML2_b may also be formed.

An upper contact electrode layer containing the aforementioned metal or alloy may be formed on the third interlayer insulating layer 150 through a deposition process such as a sputtering process to fill the upper contact holes and the upper back contact hole. The upper contact electrode layer may be etched to form the second upper contact electrode CNT2_b, the second upper gate contact GC2_b, and the second upper back contact BC2_b. According to embodiments, the upper electrode UE may also be formed on the third interlayer insulating layer 150 in the display area DA through the etching process of the upper contact electrode layer.

In some embodiments, the upper contact electrode layer may be formed to have a multi-layer structure including a plurality of metal layers (e.g., Ti layer/Al layer/Ti layer).

A first via insulating layer 160 covering the second upper contact electrode CNT2_b, the second upper gate contact GC2_b, the second upper back contact BC2_b, and the upper electrode UE may be formed on the third interlayer insulating layer 150.

A first via electrode VE1 and a second via electrode VE2 may be formed on the first via insulating layer 160 in the display area DA and the peripheral circuit area PC, respectively.

The first via electrode VE1 may penetrate the first via insulating layer 160 to be in contact with or electrically connected to the upper surface of the first upper contact electrode CNT1_b. The second via electrode VE2 may penetrate the first via insulating layer 160 to be in contact with or electrically connected to the upper surface of the second upper contact electrode CNT2_b.

For example, the first via insulating layer 160 may be partially etched to form first via holes which expose the upper surfaces of the first upper contact electrode CNT1_b and the second upper contact electrode CNT2_b, respectively. A via electrode layer containing the aforementioned metal or alloy may be formed on the first via insulating layer 160 while filling the first via holes. The via electrode layer may be partially etched to form the first via electrode VE1 and the second via electrode VE2.

The via electrode layer may also be formed to have a multi-layer structure including a plurality of metal layers (e.g., Ti layer/Al layer/Ti layer).

A second via insulating layer 170 covering the first via electrode VE1 and the second via electrode VE2 may be formed on the first via insulating layer 160. A pixel electrode PE electrically connected to the first via electrode VE1 may be formed on the second via insulating layer 170.

The first and second via insulating layers 160 and 170 may be formed through a coating process such as a spin coating process or a slit coating process to include an organic insulating material such as polyimide, epoxy-based resin, acrylic-based resin, polyester, siloxane-based resin, benzo cyclobutene (BCB), and/or the like.

The light-emitting element including a pixel electrode PE, a light-emitting part EL, and a counter electrode CE may be stacked on the second via insulating layer 170. In some embodiments, the pixel electrode PE may be electrically connected to the first lower contact electrode CNT1_a of the first lower transistor TR1_a through the first upper contact electrode CNT1_b and the first via electrode VE1.

The pixel electrode PE may be provided as an anode and may include a high work function conductive material which promotes hole injection. The pixel electrode PE may be provided as a transmissive electrode. The pixel electrode PE may include a transparent conductive oxide such as indium tin oxide (ITO), indium zinc oxide (IZO), zinc oxide (ZnO), indium tin zinc oxide (ITZO), and/or the like.

The pixel electrode PE may also be provided as a semi-transmissive electrode or a reflective electrode. The pixel electrode PE may include a metal selected from Ag, Mg, Cu, Al, Pt, Pd, Au, Ni, Nd, Ir, Cr, Li, Ca, LiF, Mo, Ti, W, In, Sn, and Zn or an alloy of two or more thereof.

The pixel electrode PE may have a single-layer structure or a multi-layer structure. For example, the pixel electrode PE may have a three-layer structure of ITO/Ag/ITO or ITO/Al/ITO.

For example, the second via insulating layer 170 may be partially etched to form a second via hole which exposes the upper surface of the first via electrode VE1. A pixel electrode layer filling the second via hole may be formed on the second via insulating layer 170 through a deposition process such as a sputtering process. The pixel electrode layer may be partially etched to form the pixel electrode PE. The pixel electrodes PE may be individually and independently formed for each of a plurality of pixels.

A pixel definition layer PDL may be formed on the second via insulating layer 170 to expose at least a portion of the upper surface of the pixel electrode PE. The pixel definition layer PDL may cover a peripheral region of the pixel electrode PE. An opening may be defined by a sidewall of the pixel definition layer PDL.

A light-emitting area (or pixel area) may be defined by the sidewall of the pixel definition layer PDL. The light-emitting area may correspond to a planar shape, planar size, etc. of the opening For example, a green light-emitting area, a blue light-emitting area, and a red light-emitting area may be separated and defined by the pixel definition layer PDL. Accordingly, the light-emitting elements may include a blue light-emitting element, a green light-emitting element, and a red light-emitting element.

In some embodiments, the light-emitting elements may all be white light-emitting elements or blue light-emitting elements.

In an embodiment, the pixel definition layer PDL may be formed by applying a photosensitive organic material such as polysiloxane resin, polyimide resin, acrylic resin, and/or the like and then by performing an exposure and development process. In an embodiment, the pixel definition layer PDL may also be formed through a printing process such as an inkjet printing process using a polymer material or an inorganic material.

In some embodiments, a spacer SPC may be formed on the upper surface of the pixel definition layer PDL. The spacer SPC may be formed using the photosensitive organic material or an inorganic insulating material. The spacer SPC may create a step difference in each pixel or light-emitting area, which can facilitate the pixel-by-pixel patterning of a light-emitting layer included in the light-emitting part EL.

The light-emitting part EL may be formed on the pixel electrode PE and the pixel definition layer PDL. The light-emitting part EL may include an organic light-emitting layer which is independently patterned for each of the red, green, and blue pixels to generate different color lights for each pixel.

In an embodiment, the light-emitting part EL may extend continuously and commonly across a plurality of pixels. In this case, the light-emitting part EL may include a white light-emitting layer or a blue light-emitting layer. In an embodiment, the light-emitting part EL may include light-emitting layers corresponding to a plurality of different color lights and may include a stacked structure in a tandem structure.

The light-emitting part EL may be formed to include an organic light-emitting material through thermal deposition, evaporation deposition, vacuum deposition, spin coating, inkjet printing, laser printing, casting, laser thermal transfer, and/or the like.

The counter electrode CE may be formed on the light-emitting part EL, the pixel definition layer PDL, and the spacer SPC. The counter electrode CE may be a common electrode provided commonly and continuously for a plurality of light-emitting areas or pixels.

The counter electrode CE may be provided as an electron injection electrode or a cathode. The counter electrode CE may include a metal, alloy, electrically conductive compound, and/or the like with a low work function.

For example, the counter electrode CE may include lithium (Li), silver (Ag), magnesium (Mg), aluminum (Al), aluminum-lithium (Al-Li), calcium (Ca), magnesium-indium (Mg-In), magnesium-silver (Mg-Ag), ytterbium (Yb), silver-ytterbium (Ag-Yb), ITO, IZO, and/or the like. These may be used alone or in a combination of two or more.

The counter electrode CE may be provided as a transmissive electrode, a semi-transmissive electrode, or a reflective electrode. The counter electrode CE may have a single-layer structure or a multi-layer structure.

The light-emitting part EL may further include a hole transport layer and an electron transport layer. According to embodiments, the hole transport layer, the light-emitting layer, the electron transport layer, and the counter electrode CE may be sequentially stacked from the upper surface of the pixel electrode PE.

For example, the hole transport layer may include a hole transport material such as m-MTDATA (4,4',4"-[tris(3-methylphenyl)phenylamino] triphenylamine), TDATA (4,4'4"-tris(N,N-diphenylamino)triphenylamine), 2-TNATA (4,4',4"-tris[N(2-naphthyl)-N-phenylamino]-triphenylamine), NPB (N,N'-di(naphthalene-l-yl)-N,N'-diphenyl-benzidine), TPD (N,N'-bis(3-methylphenyl)-N,N'-diphenyl-[1,1'-biphenyl]-4,4'-diamine), TCTA (4,4',4"-tris(N-carbazolyl)triphenylamine), PEDOT/PSS (poly(3,4-ethylenedioxythiophene)/poly(4-styrenesulfonate)), and/or the like.

For example, the electron transport layer may include an electron transport material such as an anthracene-based compound, Alq3 (tris(8-hydroxyquinolinato)aluminum), TPBi (1,3,5-Tri(1-phenyl-1H-benzo[d]imidazol-2-yl)benzene), BCP (2,9-dimethyl-4,7-diphenyl-1,10-phenanthroline), Bphen (4,7-diphenyl-1,10-phenanthroline), TAZ (3-(4-biphenylyl)-4-phenyl-5-tert-butylphenyl-1,2,4-triazole), NTAZ (4-(naphthalen-1-yl)-3,5-diphenyl-4H-1,2,4-triazole), tBu-PBD (2-(4-biphenylyl)-5-(4-tert-butylphenyl)-1,3,4-oxadiazole), BAlq (bis(2- methyl-8-quinolinolato-N1,O8)-(1,1'-biphenyl-4-olato)aluminum), and/or the like.

In some embodiments, a hole injection layer may be further disposed between the pixel electrode PE and the hole transport layer. An electron injection layer may be further disposed between the counter electrode CE and the electron transport layer.

In some embodiments, the light-emitting layer included in the light-emitting part EL may be exclusively patterned within the light-emitting area defined by the pixel definition layer PDL. Accordingly, the light-emitting layer may be separated from each other in the form of spaced islands for each of the plurality of pixels.

In some embodiments, the layers included in the light-emitting part EL (e.g., the hole transport layer and the electron transport layer) may extend continuously and commonly across the upper surfaces of the plurality of light-emitting areas and the pixel definition layer PDL.

An organic light-emitting diode element may be formed by the pixel electrode PE, the light-emitting part EL, and the counter electrode CE.

Relative to the structure shown in FIG. 2, an encapsulation layer (not shown) may be formed on the counter electrode CE. The encapsulation layer may be disposed on the pixel definition layer PDL and the light-emitting elements to protect the light-emitting elements from moisture or oxygen.

The encapsulation layer may include an inorganic layer including silicon nitride (SiNx), silicon oxide (SiOx), indium tin oxide, indium zinc oxide, or any combination thereof, an organic layer including polyethylene terephthalate, polyethylene naphthalate, polycarbonate, polyimide, polyethylene sulfonate, polyoxymethylene, polyarylate, hexamethyldisiloxane, acrylic-based resin (e.g., polymethylmethacrylate, polyacrylic acid, etc.), epoxy-based resin (e.g., AGE (aliphatic glycidyl ether), etc.) or a combination thereof, or a combination of the inorganic layer and the organic layer.

The encapsulation layer may be formed to have a single-layer structure or a multi-layer structure. In some embodiments, the encapsulation layer may have a sequentially stacked structure of a first inorganic layer, an organic layer, and a second inorganic layer.

In some embodiments, a color control layer overlapping the light-emitting part EL may be disposed over the encapsulation layer. The color control layer may include a color conversion layer including quantum dots and/or a color filter.

According to the embodiments described above, the lower back metal patterns BML1_a and BML2_a are embedded within the barrier layer 105, such that the step difference may be reduced from a lower structure of the display device. Here, a lower structure of the display device may mean lower (material) layers below overlapping stacked circuit elements (like transistors, capacitors, etc.) and providing a base stack of layers on which the stacked circuit elements are disposed. Accordingly, even when a plurality of transistors are stacked vertically in the peripheral circuit area PC and the pixel driving transistor (e.g., the first lower transistor TR1_a) and the storage capacitor Cst are stacked vertically in the display area DA, the step difference occurring in each element or layer of the display device which is above the lower structure may be reduced.

Therefore, disconnection of the active layer, short-circuits between wirings or electrodes, and/or the like that occur as the step difference in each layer above the lower structure increases may be suppressed.

Furthermore, by including the protrusion PS in the lower back metal patterns BML1_a and BML2_a, the resistance (e.g., electrical resistance) of the lower back metal patterns BML1_a and BML2_a may be reduced. Accordingly, back gate characteristics and/or source-sink characteristics may be enhanced through the lower back metal patterns BML1_a and BML2_a.

FIG. 3 is a partially enlarged cross-sectional view illustrating a shape of a lower back metal pattern of a display device according to embodiments.

Referring to FIG. 3, as described with reference to FIG. 2, the lower back metal pattern BMLa may penetrate the barrier layer 105 and may include the protrusion PS.

The upper surface of the lower back metal pattern BMLa may include a first surface 50a, a second surface 50b, and a third surface 50c. The first surface 50a may correspond to the upper surface of the protrusion PS and may be located above the upper surface 105a of the barrier layer 105. In other words, the first surface 50a may be higher than the upper surface 105a of the barrier layer 105, relative to a reference surface like an upper surface of the base substrate 100.

The third surface 50c may correspond to the upper surface of the peripheral region of the lower back metal pattern BMLa excluding the protrusion PS. The third surface 50c may be located on substantially the same plane as the upper surface 105a of the barrier layer 105. That is, the third surface 50c may be substantially coplanar with the upper surface 105a of the barrier layer 105. As shown in FIG. 2, the third surface 50c may be provided as a contact surface at which the lower surfaces of the lower contact electrodes CNT1_a and CNT2_a contact the lower back metal pattern BMLa. While the lower back metal pattern BMLa may penetrate the barrier layer 105, a protruded portion of the lower back metal pattern BMLa extends further than the upper surface 105a to define the protrusion PS.

The second surface 50b may be an inclined surface connecting the first surface 50a and the third surface 50c to each other.

As described above, the lower back metal pattern BMLa may completely penetrate the barrier layer 105 and may be in contact with the base substrate 100.

According to embodiments, a thickness of the protrusion PS may be smaller than a thickness of the lower back metal pattern BMLa excluding the protrusion PS (or, the thickness of the barrier layer 105). Accordingly, an increase in the step difference due to the protrusion PS may be prevented. In some embodiments, the thickness of the protrusion PS may be 1/2 or less, 1/3 or less, or 1/4 or less of the thickness of a remaining portion of the lower back metal pattern BMLa excluding the protrusion PS (or, the thickness of the barrier layer 105).

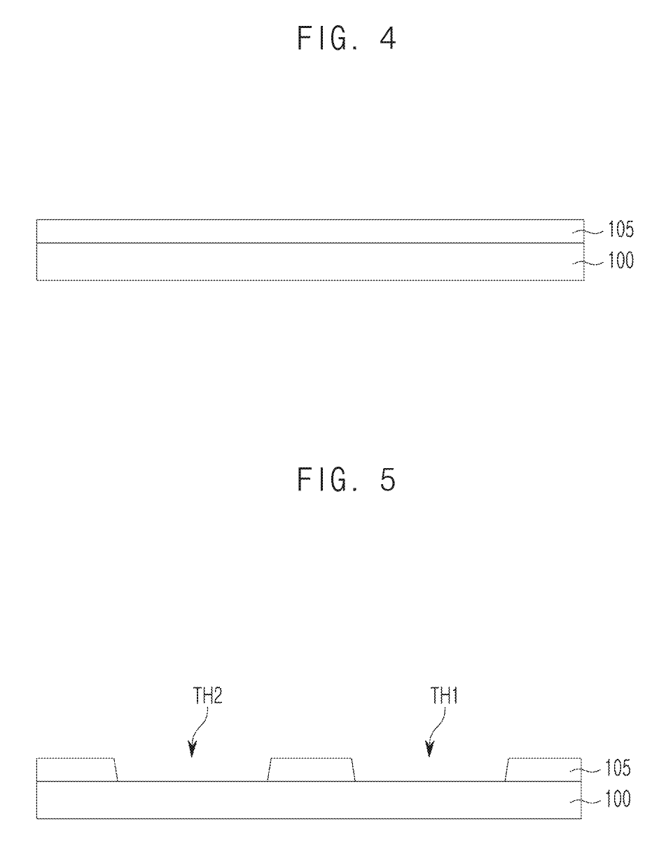

FIGS. 4 to 9 are schematic cross-sectional views illustrating a method of manufacturing (or providing) a display device according to embodiments. Detailed descriptions of configurations, materials, and processes which are substantially the same as or similar to those described with reference to FIG. 2 will be omitted.

Referring to FIG. 4, a barrier material layer of the barrier layer 105 may be formed (or provided) on the base substrate 100.

Referring to FIG. 5, the barrier material layer of the barrier layer 105 may be partially etched through a photolithography process to form a first trench TH1 and a second trench TH2. The first trench TH1 and the second trench TH2 may be formed in the display area DA and the peripheral circuit area PC, respectively. The first trench TH1 and the second trench TH2 may correspond to the lower back metal pattern BMLa.

The first trench TH1 and the second trench TH2 may completely penetrate the barrier layer 105 in the vertical direction. The upper surface of the base substrate 100 may be exposed to outside the barrier layer 105, by the first trench TH1 and the second trench TH2.

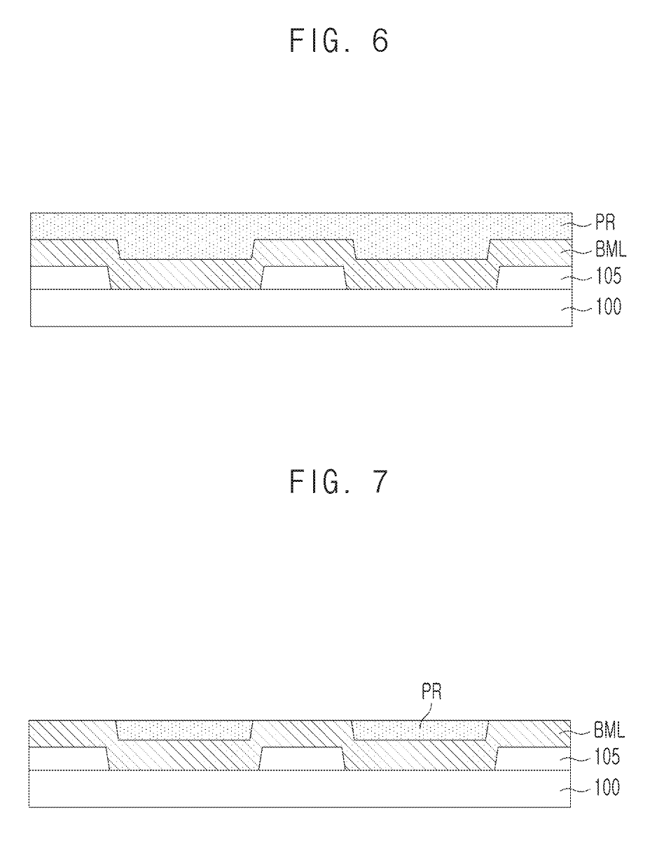

Referring to FIG. 6, a lower back metal layer BML which fills the first trench TH1 and the second trench TH2 may be formed on the barrier layer 105. The lower back metal layer BML may extend out of the trenches to be disposed on the barrier layer 105.

A sacrificial material layer of a sacrificial layer PR may be formed on the lower back metal layer BML. The sacrificial material layer of the sacrificial layer PR may be formed using a photoresist material through a coating process such as a spin coating process or a slit coating process.

Referring to FIG. 7, an upper surface of the sacrificial layer PR may be planarized through an etch-back process to remove an upper thickness portion of the sacrificial material layer. As shown in FIG. 7, as the upper surface of the sacrificial layer PR is planarized, the upper surface of the lower back metal layer BML may be exposed to outside the sacrificial layer PR. The upper surface of the lower back metal layer BML may be exposed at positions adjacent to the trenches (e.g., the first trench TH1 and the second trench TH2). An exposed portion of the lower back metal layer BML may be adjacent to the sacrificial layer PR.

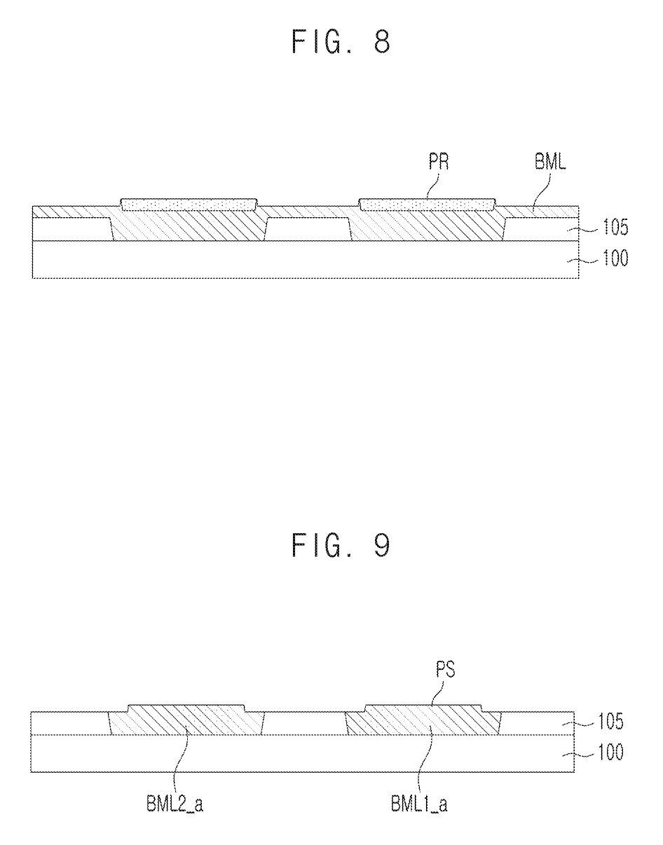

Referring to FIG. 8, as the etch-back process continues, a height difference may occur between the upper surfaces of the lower back metal layer BML and the sacrificial layer PR. According to embodiments, an etching rate for the lower back metal layer BML (e.g., an etching rate for a metal layer) may be controlled to be greater than an etching rate for the sacrificial layer PR (e.g., an etching rate for an organic layer such as a photoresist layer).

Therefore, an etching amount of the lower back metal layer BML around (e.g., directly adjacent to) the sacrificial layer PR may be relatively increased, and the upper surface of the lower back metal layer BML may be located below the upper surface of the sacrificial layer PR. Here, a first step is formed by upper surfaces of the sacrificial layer PR and the lower back metal layer BML.

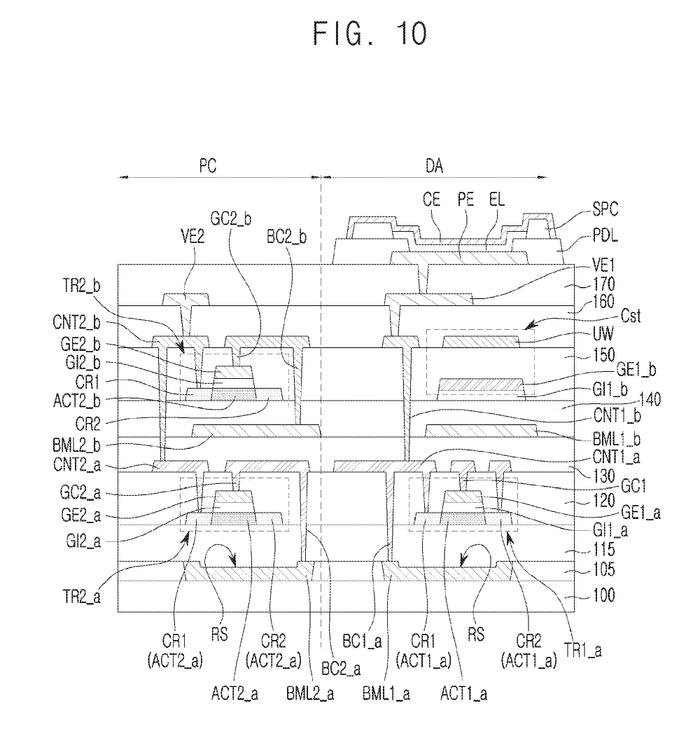

Referring to FIG. 9, the etch-back process may be performed until the barrier material layer is exposed at the upper surface of the barrier layer 105. Accordingly, the sacrificial layer PR may be substantially completely removed by the etch-back process.

As described above, according to an etch-back condition where the etching rate for the sacrificial layer PR is relatively reduced, a portion of the lower back metal layer BML covered by the sacrificial layer PR may not etched or may be etched by a relatively small amount. Therefore, the first lower back metal pattern BML1_a and the second lower back metal pattern BML2_a including the protrusion PS may be formed within the first trench TH1 and the second trench TH2, respectively, from the lower back metal layer BMLa.

As described above, the first lower back metal pattern BML1_a and the second lower back metal pattern BML2_a may be formed within the trenches TH1 and TH2 which penetrate the barrier layer 105. Therefore, a depth of the trenches TH1 and TH2 may be uniformly formed with the thickness of the barrier layer 105, and the thicknesses of the first lower back metal pattern BML1_a and the second lower back metal pattern BML2_a may also be uniformly formed.

Subsequently, as described with reference to FIG. 2, the transistor, the storage capacitor, the light-emitting element, and the like may be formed on the barrier layer 105 and the lower back metal patterns BML1_a and BML2_a.

Here, an embodiment of providing a display device includes providing a barrier layer 105 on a base substrate 100, providing a trench which penetrates the barrier layer 105, by etching the barrier layer 105, sequentially providing a lower back metal layer BML which fills the trench and a sacrificial layer PR, on the base substrate 100, providing a lower back metal pattern within the trench by removing the sacrificial layer PR together with a peripheral region of the lower back metal layer BML which is adjacent to the trench, through an etch-back process, providing a lower transistor on the lower back metal pattern, and providing a light-emitting element electrically connected to the lower transistor. The etch-back process may include an etching rate for the lower back metal layer which is greater than an etching rate for the sacrificial layer, and the removing of the sacrificial layer and the peripheral region of the lower back metal layer defines a protrusion of the lower back metal pattern which overlaps the trench.

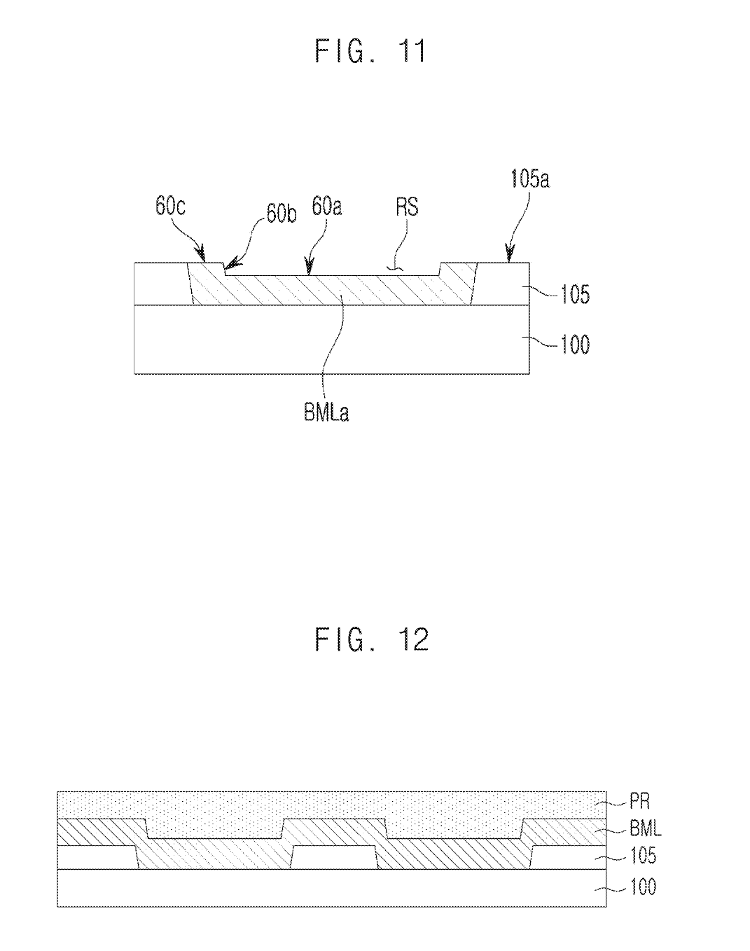

FIG. 10 is a schematic cross-sectional view illustrating a display device according to embodiments, and FIG. 11 is a partially enlarged cross-sectional view illustrating a shape of a lower back metal pattern of a display device according to embodiments.

The display device of FIG. 10 may have substantially the same or similar configurations and structures as the display device of FIG. 2, except for the shape of the lower back metal pattern. Therefore, detailed descriptions of configurations, structures, and processes which are substantially the same as or similar to those described with reference to FIG. 2 will be omitted.

Referring to FIGS. 10 and 11, the lower back metal pattern BMLa may include a recess RS which overlaps the trench in the barrier layer 105. According to embodiments, the first lower back metal pattern BML1_a and the second lower back metal pattern BML2_a formed in the display area DA and the peripheral circuit area PC, respectively, may each include the recess RS.

As shown in FIG. 11, the upper surface of the lower back metal pattern BMLa may include a first surface 60a, a second surface 60b, and a third surface 60c. The first surface 60a may correspond to the lower surface (e.g., the bottom) of the recess RS and may be located below the upper surface 105a of the barrier layer 105.

The third surface 60c may correspond to the upper surface of the peripheral region of the recess RS of the lower back metal pattern BMLa. The third surface 60c may be located on substantially the same plane as the upper surface 105a of the barrier layer 105. That is, the third surface 60c may be substantially coplanar with the upper surface 105a of the barrier layer 105. As shown in FIG. 10, the third surface 60c may be provided as a contact surface at which the lower surfaces of the lower contact electrodes CNT1_a and CNT2_a contact the respective lower back metal pattern.

The second surface 60b may be an inclined surface connecting the first surface 60a and the third surface 60c.

As described above, the lower back metal pattern BMLa may completely penetrate the barrier layer 105 and may be in contact with the base substrate 100. Accordingly, the thickness of the lower back metal pattern BMLa may be uniformly controlled.

Furthermore, since the lower back metal pattern BMLa includes the recess RS, the reduction effect of the step difference caused by the lower back metal pattern BMLa may be implemented efficiently.

According to embodiments, the depth of the recess RS may be 1/2 or less of the total thickness of the lower back metal pattern BMLa (or, the thickness of the barrier layer 105). Therefore, an increase in resistance due to the recess RS may be prevented, and thus the effect of reducing the step difference may be implemented. In some embodiments, the depth of the recess RS may be 1/3 or less, 1/4 or less, or 1/5 or less of the total thickness of the lower back metal pattern BMLa (or, the thickness of the barrier layer 105).

FIGS. 12 to 15 are schematic cross-sectional views illustrating a method of manufacturing (or providing) a display device according to embodiments.

Referring to FIG. 12, processes substantially the same as or similar to the processes described with reference to FIGS. 4 to 6 may be performed. Accordingly, the barrier layer 105 may be formed on the base substrate 100, and the trenches TH1 and TH2 (see FIG. 5) may be formed.

Subsequently, the lower back metal layer BML which fill the trenches TH1 and TH2 and the sacrificial layer PR may be sequentially formed on the barrier layer 105.

Referring to FIG. 13, an upper surface of the sacrificial layer PR may be planarized through an etch-back process. As shown in FIG. 13, as the upper surface of the sacrificial layer PR is planarized, the upper surface of the lower back metal layer BML may be exposed.

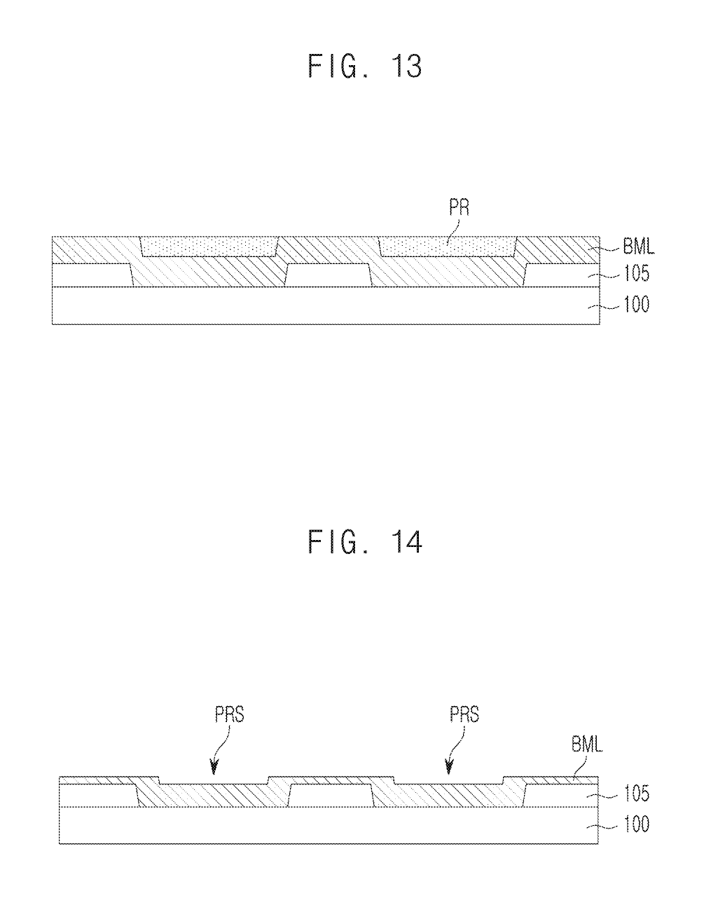

Referring to FIG. 14, as the etch-back process continues, a height difference may occur between the upper surfaces of the lower back metal layer BML and the sacrificial layer PR. According to embodiments, an etching rate for the lower back metal layer BML (e.g., an etching rate for a metal layer) may be controlled to be smaller than an etching rate for the sacrificial layer PR (e.g., an etching rate for an organic layer such as a photoresist layer).

Therefore, an etching amount of the lower back metal layer BML around the sacrificial layer PR may be relatively reduced. As the sacrificial layer PR is removed together with the lower back metal layer BML adjacent to the sacrificial layer PR, a preliminary recess PRS may be formed. Here, the sacrificial layer PR is completely removed along with an upper thickness portion of the lower back metal layer BML adjacent to the sacrificial layer PR.

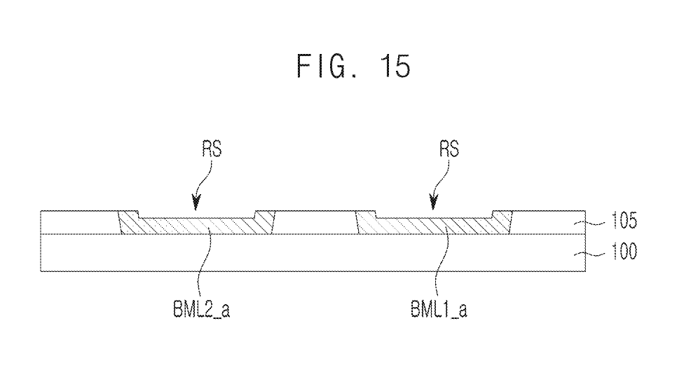

Referring to FIG. 15, as the etch-back process proceeds further, since the sacrificial layer is completely removed, reduced-thickness portion of the lower back metal layer BML is further etched to completely remove the lower back metal layer BML adjacent to the respective trenches and expose the upper surface of the barrier layer 105 which is adjacent to the respective trenches. The lower back metal layer BML may be additionally etched at the preliminary recess PRS, thereby forming the recess RS having a depth taken from the upper surface 105 of the barrier layer 105.

Subsequently, as described with reference to FIG. 10 (similar to the description related to FIG. 2), the transistor, the storage capacitor, the light-emitting element, and the like may be formed on the barrier layer 105 and the lower back metal patterns BML1_a and BML2_a having respective recesses.

Here, the etch-back process may include an etching rate for the lower back metal layer which is lower than an etching rate for the sacrificial layer, and the removing of the sacrificial layer and the peripheral region of the lower back metal layer defines a recess of the lower back metal pattern which overlaps the trench.

Similar to that described for the lower structure of FIG. 2, according to the embodiments described above, the lower back metal patterns BML1_a and BML2_a are embedded within the barrier layer 105, such that the step difference may be reduced from the lower structure of the display device. Therefore, disconnection of the active layer, short-circuits between wirings or electrodes, and/or the like that occur as the step difference in each layer above the lower structure increases may be suppressed.

Furthermore, by including the recess RS in the lower back metal patterns BML1_a and BML2_a, the resistance (e.g., electrical resistance) of the lower back metal patterns BML1_a and BML2_a may be reduced. Accordingly, back gate characteristics and/or source-sink characteristics may be enhanced through the lower back metal patterns BML1_a and BML2_a.

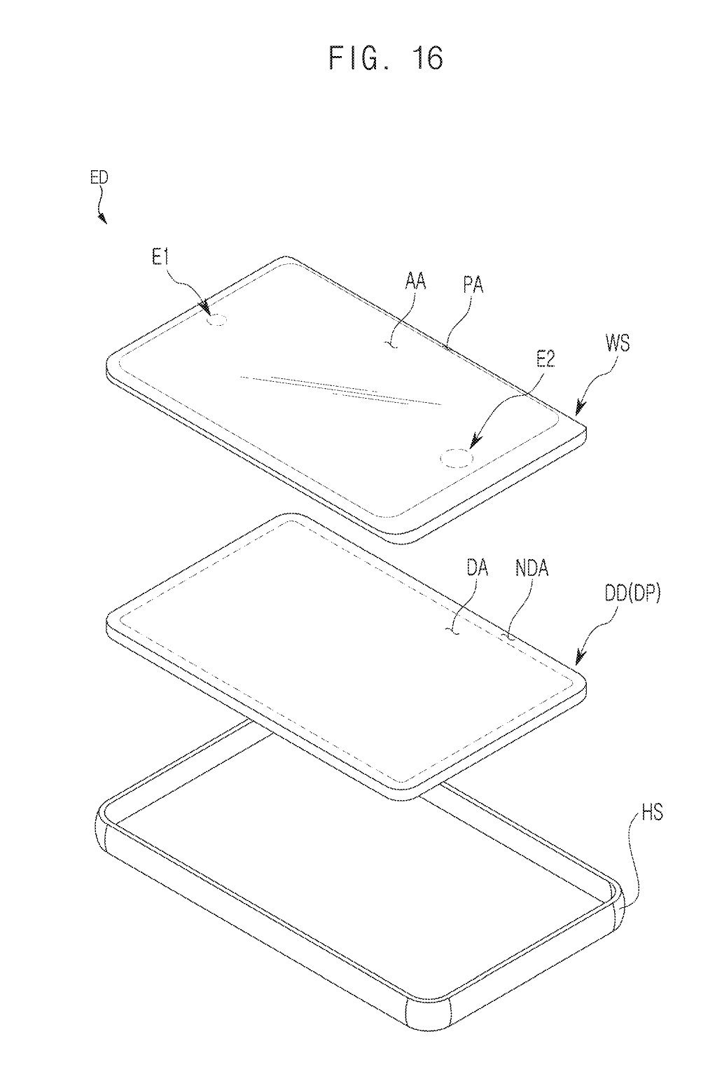

FIG. 16 is an exploded perspective view illustrating an electronic device ED according to embodiments.

According to embodiments, the electronic device ED may be implemented in the form of a mobile phone (or also referred to as a smartphone), a personal computer (PC), a tablet PC, and/or the like including the display device described above.

Referring to FIG. 16, the electronic device ED may include a window structure WS, a display device DD, and a housing HS. The display device DD may include a display panel Although the present disclosure has been described above with reference to embodiments thereof, it will be understood by those skilled in the art that various modifications and changes can be made to the present disclosure without departing from the spirit and scope of the present disclosure as set forth in the following claims.

DP including the transistor and the light-emitting element described above. The housing HS, the display device DD, and the window structure WS may be sequentially stacked in the third direction.

The window structure WS may provide an external display surface recognized from outside of the electronic device ED, such as by the user. The external display surface may be a viewing surface of the electronic device like the mobile phone, and may include a transparent material film. For example, the window structure WS may include glass (e.g., ultra-thin glass (UTG)), a hard-coating film, a plastic film, and/or the like.

An outer surface of the window structure WS may include an active area AA and a peripheral area PA which is adjacent to the active area AA. The active area AA is where an image of the display device DD is substantially displayed. The active area AA may provide a surface where the user's touch/command is input to the electronic device ED. The peripheral area PA may substantially correspond to a bezel area of the electronic device ED. An image may not be displayed at the peripheral area PA, without being limited thereto.

The display device DD and/or the display panel DP may include a display area DA and a non-display area NDA. The display area DA of the display panel DP may substantially correspond to or overlap the active area AA of the window structure WS. The non-display area NDA of the display panel DP may substantially correspond to or overlap the peripheral area PA of the window structure WS. In some embodiments, the peripheral area PA of the window structure WS may further include a margin (planar) area which does not overlap the non-display area NDA of the display panel DP.

In some embodiments, functional element areas E1 and E2 may be included within the active area AA of the window structure WS. For example, the first functional element area E1 may be included at one end of the active area AA and may be implemented, for example, in the form of a camera hole. The second functional element area E2 may be provided as a fingerprint sensing area.

For example, a sensor structure for touch sensing or fingerprint sensing may be disposed within the display panel DP or between the window structure WS and the display panel DP.

The housing HS may be provided as a support frame or a rear housing for the display device DD or the electronic device ED. A cover panel may also be disposed between the housing HS and the display panel DP. The housing HS or the cover panel may include a plate (e.g., a SUS plate) which supports the display panel DP. The housing HS or the cover panel may also include an elastic body for shock absorption of the display device DD.

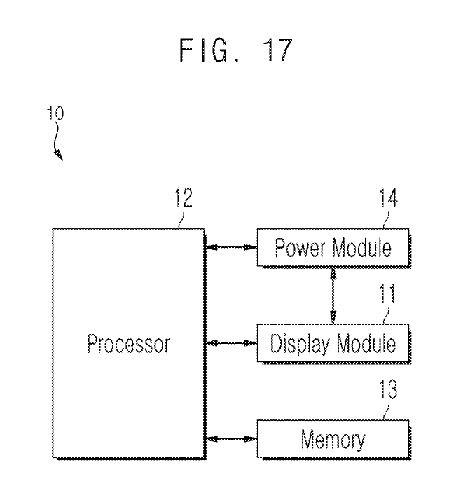

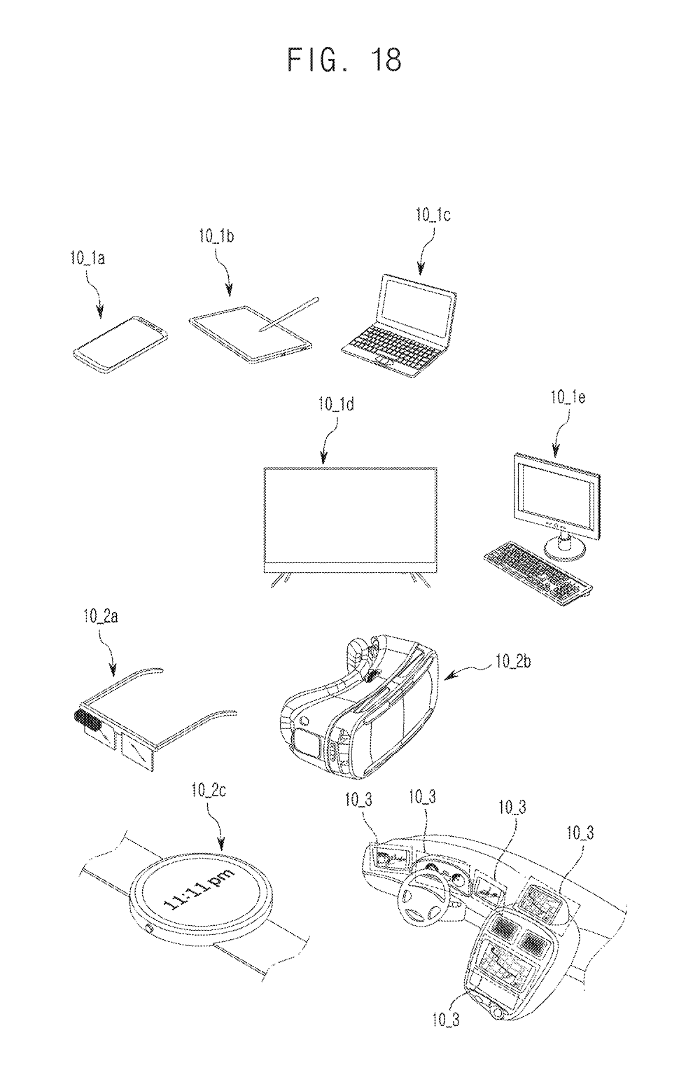

FIG. 17 is a block diagram illustrating an electronic device 10 according to embodiments.

Referring to FIG. 17, the electronic device 10 may include a display module 11, a processor 12, a memory 13, and a power module 14.

The processor 12 may include a central processing unit (CPU), an application processor (AP), a graphic processing unit (GPU), a communication processor (CP), an image signal processor (ISP), and/or a controller.

The memory 13 may store data information necessary for the operation of the processor 12 or the display module 11. When the processor 12 executes an application stored in the memory 13, a video data signal and/or an input control signal may be transmitted to the display module 11, and the display module 11 may process the received signal to output video information through a display screen.

The power module 14 may include a power supply module such as a power adapter, a battery device, and/or the like and a power conversion module which converts the power supplied by the power supply module to generate the power necessary for the operation of the electronic device 10.

At least one of the components of the electronic device 10 described above may be included in the display device according to the embodiments described above. In addition, some of individual modules functionally included in one module may be included in the display device, while others may be provided separately from the display device. For example, the display module 11 may include a display device, and the processor 12, the memory 13, and the power module 14 may be provided in the form of other devices within the electronic device 10 other than the display device.

FIG. 18 is schematic diagrams of embodiments the electronic device of FIG. 17.

Referring to FIG. 18, non-limiting examples of various electronic devices to which display devices according to embodiments are applied may include image display electronic devices such as a smart phone 10_1a, a tablet PC 10_1b, a laptop 10_1c, a television 10_1d, a desk monitor 10_1e, and/or the like, wearable electronic devices including display modules such as smart glasses 10_2a, a head-mounted display 10_2b, a smart watch 10_2c, and/or the like, and vehicle electronic devices 10_3 including display modules such as an automobile's instrument panel, a CID (Center Information Display) placed on center fascia and dashboard, a room mirror display, and/or the like. The electronic devices may also include virtual reality glasses or augmented reality glasses.

Although the present disclosure has been described above with reference to embodiments thereof, it will be understood by those skilled in the art that various modifications and changes can be made to the present disclosure without departing from the spirit and scope of the present disclosure as set forth in the following claims.

What is claimed is:

1. A display device comprising:
a base substrate;
a barrier layer on the base substrate;
a lower back metal pattern penetrating the barrier layer at a trench of the barrier layer, the lower back metal pattern defining a protrusion or a recess of the lower back metal pattern which overlaps the trench;
a lower transistor overlapping the lower back metal pattern, the lower transistor including a lower active layer and a lower gate electrode which is on the lower active layer; and
a light-emitting element electrically connected to the lower transistor.

2. The display device of claim 1, further comprising a lower contact pattern which electrically connects the lower active layer to the lower back metal pattern, the lower contact pattern including:
a lower contact electrode at which the lower contact pattern is electrically connected to the lower active layer; and
a lower back contact at which the lower contact pattern is electrically connected to the lower back metal pattern.

3. The display device of claim 1, further comprising a lower contact pattern which electrically connects the lower gate electrode to the lower back metal pattern:
a lower gate contact at which the lower contact pattern is electrically connected to the lower gate electrode; and
a lower back contact at which the lower contact pattern is electrically connected to the lower back metal pattern.

4. The display device of claim 1, wherein
the base substrate includes a display area and a peripheral circuit area which is adjacent to the display area,
the lower back metal pattern is provided in plural on the base substrate, including a first lower back metal pattern in the display area and a second lower back metal pattern in the peripheral circuit area of the base substrate, and
each of the first lower back metal pattern and the second lower back metal pattern includes the protrusion or the recess.

5. The display device of claim 4, wherein the lower transistor is provided in plural on the base substrate including a first lower transistor in the display area and a second lower transistor in the peripheral circuit area.

6. The display device of claim 5, further comprising:
a first lower back contact electrically connecting the first lower transistor to the first lower back metal pattern; and
a second lower back contact electrically connecting the second lower transistor to the second lower back metal pattern.

7. The display device of claim 5, further comprising a storage capacitor overlapping the first lower transistor in the display area of the base substrate.

8. The display device of claim 7, further comprising a first upper back metal pattern between the first lower transistor and the storage capacitor.

9. The display device of claim 5, further comprising a second upper transistor overlapping the second lower transistor in the peripheral circuit area of the base substrate.

10. The display device of claim 9, further comprising a contact electrode electrically connecting the second upper transistor and the second lower transistor to each other.

11. The display device of claim 9, further comprising a second upper back metal pattern between the second lower transistor and the second upper transistor.

12. The display device of claim 1, wherein in the trench, a lower surface of the lower back metal pattern is in contact with the base substrate.

13. The display device of claim 1, wherein
the lower back metal pattern includes the protrusion, and
a thickness of the protrusion is smaller than a thickness of a peripheral region of the lower back metal pattern which excludes the protrusion.

14. The display device of claim 1, wherein
the lower back metal pattern includes the recess, and
a depth of the recess is less than or equal to 1/2 of a total thickness of the lower back metal pattern.

15. The display device of claim 1, wherein
a peripheral region of the lower back metal pattern is adjacent to the recess or the protrusion, and
an upper surface of the lower back metal pattern at the peripheral region is coplanar with an upper surface of the barrier layer which is adjacent to the lower back metal pattern.

16. A method of providing a display device, comprising:
providing a barrier layer on a base substrate;
providing a trench which penetrates the barrier layer, by etching the barrier layer;
sequentially providing a lower back metal layer which fills the trench and a sacrificial layer, on the base substrate;
providing a lower back metal pattern within the trench by removing the sacrificial layer together with a peripheral region of the lower back metal layer which is adjacent to the trench, through an etch-back process;
providing a lower transistor on the lower back metal pattern; and
providing a light-emitting element electrically connected to the lower transistor.

17. The method of claim 16, wherein
the etch-back process includes an etching rate for the lower back metal layer which is greater than an etching rate for the sacrificial layer, and
the removing of the sacrificial layer and the peripheral region of the lower back metal layer defines a protrusion of the lower back metal pattern which overlaps the trench.

18. The method of claim 16, wherein
the etch-back process includes an etching rate for the lower back metal layer which is lower than an etching rate for the sacrificial layer, and
the removing of the sacrificial layer and the peripheral region of the lower back metal layer defines a recess of the lower back metal pattern which overlaps the trench.

19. An electronic device comprising:
a display device;
a memory device; and
a processor configured to execute data included in the memory device to control an operation of the display device,
wherein the display device includes:
a base substrate;
a barrier layer on the base substrate;
a lower back metal pattern penetrating the barrier layer at a trench of the barrier layer, the lower back metal pattern defining a protrusion or a recess of the lower back metal pattern which overlaps the trench;
a lower transistor overlapping the lower back metal pattern, the lower transistor including a lower active layer and a lower gate electrode which is on the lower active layer; and
a light-emitting element electrically connected to the lower transistor.

20. The electronic device of claim 19, wherein the electronic device is implemented as virtual reality glasses, augmented reality glasses, a smartphone, a tablet computer, a laptop, a television, a desk monitor, smart glasses, a head-mounted display, a smart watch or a vehicle display.
